(19) United States
(12) Patent Application Publication
(10) Pub. No.: US 2018/0287020 A1
(43) Pub. Date: Oct. 4, 2018

(54) LIGHT-EMITTING DIODE DEVICE, MANUFACTURING METHOD THEREFOR, AND MOLD USED THEREFOR

(71) Applicants: LUMIMICRO CORP. LTD., Yongin-si, Gyeonggi-do (KR); INDUSTRY-ACADEMIC COOPERATION FOUNDATION, YONSEI UNIVERSITY, Seoul (KR)

(72) Inventors: Cheon Soo KIM, Suwon-si, Gyeonggi-do (KR); Young Joo KIM, Goyang-si, Gyeonggi-do (KR); Min Ho SHIN, Gimcheon-si, Gyeongsangbuk-do (KR); Bo Sun SONG, Wonju-si, Gangwon-do (KR)

(73) Assignees: LUMIMICRO CORP. LTD., Yongin-si, Gyeonggi-do (KR); INDUSTRY-ACADEMIC COOPERATION FOUNDATION, YONSEI UNIVERSITY, Seoul (KR)

(21) Appl. No.: 15/531,725

(22) PCT Filed: Apr. 22, 2016
(86) PCT No.: PCT/KR2016/004239

§ 371 Date: May 30, 2017

(30) Foreign Application Priority Data
Apr. 27, 2015 (KR) 10-2015-0059253
Apr. 28, 2015 (KR) 10-2015-0060057
Apr. 29, 2015 (KR) 10-2015-0060438
Apr. 30, 2015 (KR) 10-2015-0061262

(51) Int. Cl. H01L 33/50; H01L 33/56; H01L 33/62

(52) U.S. Cl. CPC H01L 33/507; H01L 33/56; H01L 33/62; H01L 33/60; H01L 2933/005; H01L 2933/0066; H01L 2933/0041

(57) ABSTRACT

A method for manufacturing a light-emitting diode device, according to the present invention, comprises: a first step of preparing a base mold (300) having a plurality of recessed accommodation parts (A); a second step of applying fluorescent resins (320) inside the accommodation parts (A); a third step of mounting, within the accommodation parts (A), light-emitting diode chips (10) having smaller widths than those of the accommodation parts (A) such that the fluorescent resins (320) are pushed up to the top over a gap between the lateral sides of the accommodation parts (A) and the light-emitting diode chips (10) so as to allow the lateral sides of the light-emitting diode chips (10) to be surrounded by the fluorescent resins (320), thereby simultaneously obtaining a plurality of individual light-emitting diode devices; and a fourth step of separating the light-emitting diode devices from the base mold (300).

### TECHNICAL FIELD

The present invention relates to a method for manufacturing light-emitting diode devices and a pressing mold used for the method, which obtain a light-emitting diode device by previously forming a chip accommodation unit and a boundary groove in fluorescent resin through a pressing mold, mounting a light-emitting diode chip on the chip accommodation unit, and then cutting only the bottom portion of the boundary grooves.

Furthermore, the present invention relates to a method for manufacturing light-emitting diode devices, which is capable of obtaining a plurality of light-emitting diode devices without a process of cutting fluorescent resin by molding the fluorescent resin in light-emitting diode chips individually at the same time using a base mold.

Furthermore, the present invention relates to a light-emitting diode device in which a buffer layer is interposed a light-emitting diode chip and a fluorescent resin layer.

Furthermore, the present invention relates to a light-emitting diode device capable of reducing a color deviation according to an angle, which is generated due to the limit of a reflection angle when it is to improve light extraction efficiency by upward reflecting light emitted in the lateral direction of a light-emitting diode chip using an oblique reflection sidewall.

### BACKGROUND ART

A light-emitting diode (LED) refers to a semiconductor device capable of implementing light of various colors through a PN junction. As a blue light-emitting diode and an ultraviolet light-emitting diode are recently fabricated using nitrides, white light or another piece of monochromatic light can be generated using such a blue or ultraviolet light-emitting diode and a fluorescent substance, thereby widening the application range of the light-emitting diode.

At first, three light-emitting diodes of red (R), green (G) and blue (B) colors were used at the same time so that pieces of light emitted by the three light-emitting diodes are overlapped, thereby implementing white light. However, in this case, there is a problem in that the three light-emitting diodes had to be installed. Accordingly, recently, white light is obtained through one light-emitting diode by implementing white light by a combination of the light-emitting diode and a fluorescent substance as described above.

For example, white light is obtained by disposing a fluorescent layer that emits light of yellowish green or yellow over a blue light-emitting diode that emits light having a wavelength of 430 nm-480 nm using part of corresponding blue light as an excitation source so that the blue light emitted by the blue light-emitting diode and the yellowish green or yellow light of the fluorescent layer excited and generated by the emitted blue light are overlapped.

In a conventional technology, as disclosed in Korean Patent No. 1352967 (issued on Jan. 22, 2014), in order to obtain a fluorescent layer, a dispensing process of applying a hardening type liquefied fluorescent resin composition in which solid-state fluorescent substance particles have been dispersed in a hardening type liquefied resin composition through a dispenser was applied.

FIG. 1 is a diagram for illustrating a conventional method for manufacturing a white light-emitting diode device and is shown with reference to Korean Patent No. 1352967.

First, as in FIG. 1A, a plurality of light-emitting diode chips 10 that emit blue-series light is installed on a first sheet 1 at proper intervals so that conductive bumps 11 are attached to the first sheet 1. Spacers 3 higher than the light-emitting diode chips 10 are installed in the outskirts.

Next, as in FIG. 1B, a hardening type liquefied fluorescent resin composition 20 is applied using a dispenser so that a chip array region within the spacers 3 is filled. Such a process is called a dispensing process. In this case, transparent resin in which fluorescent substance particles emitting yellow series have been dispersed is used as the hardening type liquefied fluorescent resin composition 20. A sufficient amount of the transparent resin is applied so that the chip array region within the spacers 3 is filled.

Thereafter, as in FIG. 1C, after a second sheet 2 is attached on the spacer 3, proper pressure is applied to the second sheet 2. Accordingly, the hardening type liquefied fluorescent resin composition 20 flows into the gap between the light-emitting diode chips 10 and the first sheet 1 due to the conductive bumps 11 and is filled into the gap and at the same time, the height of the hardening type liquefied fluorescent resin composition 20 is leveled to become flat compared to the height of the spacers 3.

Next, as in FIG. 1D, fluorescent resin 21 is obtained by hardening the hardening type liquefied fluorescent resin composition 20 using a proper method, such as heat or ultraviolet rays.

Thereafter, as in FIG. 1E, a light-emitting diode device 30, such as that of FIG. 1F, is obtained by cutting the fluorescent resin 21 using a dicing apparatus. At this time, the first sheet 1 and the second sheet 2 are removed on a proper time according to circumstances before or after the dicing process.

The light-emitting diode chip 10 emits blue-series light, and the fluorescent resin 21 is excited by part of the blue-series light emitted by the light-emitting diode chip 10 and emits yellow-series light. As a result, light emitted through the fluorescent resin 21 is generally white light when viewed from the outside because the blue-series light and the yellow-series light are overlapped.

In this case, the implementation of the white light is influenced by the thickness of the fluorescent resin 21 because the amount of the fluorescent substance particles included in the fluorescent resin 21 may be different depending on the thickness of the fluorescent resin 21. Accordingly, white light efficiency of the light-emitting diode device 30 obtained in a corresponding dicing process is individually constant only in the case where the fluorescent resin 21 is cut so that the thickness “t” of the fluorescent resin 21 is constant in the surrounding of the light-emitting diode chip 10, thereby improving reliability of a product.

However, in accordance with the aforementioned conventional method for manufacturing light-emitting diode devices, the fluorescent resin 21 has been said to be hardened, but is polymer resin which is slightly soft. Accordingly, there is a problem in that the thickness “t” of the fluorescent resin 21 is not constant on the side of the light-emitting diode chip 10 because a deviation is generated in the cutting process. Furthermore, there is a possibility that an emission characteristic may be deteriorated because fine fragments, such as sawdust generated in the cutting process of the fluorescent resin 21, remain attached to the light-emitting diode device. Furthermore, there is a problem in that the fluorescent resin 21 is wasted because a remnant portion of the fluorescent resin 21 is present after the cutting.

Furthermore, in order for the hardening type liquefied fluorescent resin composition 20 to evenly flow into the surroundings of the light-emitting diode chips 10 during the dispensing and leveling processes, the viscosity of the hardening type liquefied fluorescent resin composition 20 needs to be low to some extent. In this case, there is a problem in that the implementation of the white light is not properly performed at the place where the fluorescent substance particles have low density because the fluorescent substance particles are irregularly distributed within the hardening type liquefied fluorescent resin composition 20 due to the sinking of the fluorescent substance particles attributable to gravity, etc. during the dispensing and leveling processes.

In the conventional white light-emitting diode device 30, the fluorescent resin layer 20 is disposed to surround the light-emitting diode chips 10 in the state in which it has come into contact with the light-emitting diode chips 10. The light-emitting diode chips 10 emit blue-series light, and the fluorescent resin layer 20 is excited by part of the blue-series light emitted by the light-emitting diode chips 10, thus emitting yellow-series light. As a result, light emitted through the fluorescent resin layer 20 is generally white light when viewed from the outside because the blue-series light and the yellow-series light are overlapped.

It is advantageous to obtain white light through light mixing when the fluorescent resin layer 20 is formed around the light-emitting diode chips 10 as described above. However, when the light-emitting diode chip 10 is driven, heat is generated to the extent that the light-emitting diode chip 10 rises up to a temperature of about 70˜80° C. Accordingly, there is a problem in that the uniformity of light extraction efficiency is significantly deteriorated because the fluorescent resin layer 20 is subjected to heat degradation. Furthermore, there is a problem in that light extraction efficiency is also reduced because light is not properly extracted to the outside due to a great difference in the refractive index between the fluorescent resin layer 20 and the light-emitting diode chip 10.

Meanwhile, Korean Patent No. 1273481 (issued on Jun. 17, 2013), Korean Utility Model No. 2014-4505 (issued on Jul. 30, 2014), etc. show a case where a reflection sidewall is used to improve light extraction efficiency of a light-emitting diode. In this case, there is a problem in that a color deviation according to an angle is generated due to the limit of a reflection angle.

FIG. 12 is a diagram for illustrating a conventional light-emitting diode device and is shown with reference to Korean Utility Model No. 2014-4505. In this case, FIG. 12A shows a wire bonding type, and FIG. 12B shows a flip chip type.

As shown in FIG. 12, a reflection body 510 includes an accommodation unit 501 of an empty space for accommodating a light-emitting diode chip 520. An accommodation unit sidewall 502 is disposed to be outward inclined upward. A lead frame 511 is disposed to be exposed at the bottom of the accommodation unit 501. The light-emitting diode chip 520 is disposed to be electrically connected to the lead frame 511 through bonding wires 521 as in FIG. 12A or is disposed to be electrically connected to the lead frame 511 through bumps 522 as in FIG. 12B.

A solid fluorescent sheet 530 is disposed on the light-emitting diode chip 520 in order to block the entire entrance of the accommodation unit 501. In the case of a wire bonding type, such as that of FIG. 12A, the solid fluorescent sheet 530 is disposed with it being separated from the light-emitting diode chip 520 to some extent so that the bonding wires 521 are not damaged. In the case of a flip chip type, such as that of FIG. 12B, the solid fluorescent sheet 530 is directly disposed on the light-emitting diode chip 520 because it does not need to be separated from the light-emitting diode chip 520. A transparent sealant 540 is disposed on the solid fluorescent sheet 530.

The fluorescent substance of the solid fluorescent sheet 530 is excited by part of blue light emitted by the light-emitting diode chip 520, thus emitting yellow light. The remaining blue light that does not contribute to the excitation passes through the solid fluorescent sheet 530 without any change. Accordingly, the yellow light and the blue light overlap and look like white light when they are viewed from the outside. At this time, light laterally emitted by the light-emitting diode chip 520 is also reflected by the accommodation unit sidewall 502 and directed toward the solid fluorescent sheet 530, thereby improving light extraction efficiency.

However, the aforementioned conventional light-emitting diode device has a disadvantage in that light that collides against the accommodation unit sidewall 502 and that is upward reflected does not properly reach the entrance edge E of the accommodation unit 501, as shown in FIG. 13. Accordingly, there is a difference in the white light implementation between the entrance edge E and central part of the accommodation unit 501. As a result, the conventional light-emitting diode device has a problem in that a great color deviation is generated depending on an angle when it is straight viewed and when it is obliquely viewed from the outside.

### PRIOR ART DOCUMENT

Korean Patent No. 1352967 (issued on Jan. 22, 2014)

Korean Patent No. 1273481 (issued on Jun. 17, 2013)

Korean Utility Model No. 2014-4505 (laid open on Jul. 30, 2014)

### DISCLOSURE

### Technical Problem

Accordingly, a first object to be solved by the present invention is to provide a method for manufacturing light-emitting diode devices and a pressing mold used for the method, which are capable of solving the aforementioned conventional problems by regularly rearranging fluorescent substance particles with high density by the pressurization of a pressing mold, performing cutting at a precise location along previously partitioned boundary grooves, and minimizing a thickness for actual cutting in such a manner that a chip accommodation unit and a boundary groove are previously formed in fluorescent resin through a pressing mold, a light-emitting diode chip is mounted on the chip accommodation unit, and only the bottom portion of the boundary grooves is cut, without using a conventional dispensing process.

A second object to be solved by the present invention is to provide a method for manufacturing light-emitting diode devices, which is capable of solving the aforementioned conventional problems by obtaining a plurality of light-emitting diode devices without a process of cutting fluorescent resin by molding the fluorescent resin in light-emitting diode chips individually at the same time.

A third object to be solved by the present invention is to provide a light-emitting diode device capable of solving the aforementioned conventional problems by minimizing the deterioration of a fluorescent resin layer attributable to heat generated from a light-emitting diode chip and reducing a difference in the refractive index between the light-emitting diode chip and a fluorescent resin layer.

A fourth object to be solved by the present invention is to provide a light-emitting diode device capable of solving the aforementioned conventional problems by improving the sidewall of an accommodation unit for accommodating a light-emitting diode chip so that a color deviation is reduced.

### Technical Solution

A method for manufacturing light-emitting diode devices according to the present invention for achieving the first object includes the steps of:

forming a concave chip accommodation unit in fluorescent resin by the pressurization of a pressing mold and at the same time, forming a boundary groove at a location spaced apart from the chip accommodation unit;

mounting a light-emitting diode chip on the chip accommodation unit; and

cutting the bottom portion of the boundary groove.

It is preferred that the boundary groove is formed deeper than the chip accommodation unit.

It is preferred that the bottom surface of the boundary groove is pointed and caved in a wedge form.

It is preferred that the step of forming the chip accommodation unit and the boundary groove is performed in the state in which the fluorescent resin is semi-solid, a hardening process is performed on the fluorescent resin before or after the step of mounting the light-emitting diode chip, and the cutting is performed after the hardening process.

It is preferred that a plurality of the chip accommodation units is disposed and the boundary grooves are disposed to surround the surrounding of the chip accommodation unit. In this case, it is preferred that a through hole penetrating the fluorescent resin is formed in a portion where the boundary grooves are intersected.

A pressing mold according to the present invention for achieving the first object is for forming concave chip accommodation units in fluorescent resin through an effect on the fluorescent resin and also for forming boundary grooves at locations spaced apart from the chip accommodation units, and includes:

a mold body;

a plurality of boundary groove formation protrusions protruded from the mold body in order to form the boundary grooves; and

a plurality of chip accommodation unit formation protrusions protruded from the mold body between the boundary groove formation protrusions in order to form the chip accommodation units.

It is preferred that the boundary groove formation protrusion is protruded more lengthily than the chip accommodation unit formation protrusion.

It is preferred that the protruded end of the boundary groove formation protrusion is pointed and formed in a wedge form.

It is preferred that the boundary groove formation protrusion is disposed to surround the surrounding of the chip accommodation unit formation protrusion. In this case, it is preferred that a through hole formation protrusion is further protruded at a portion where the boundary groove formation protrusions are intersected so that a through hole penetrating the fluorescent resin is formed at the portion where the boundary groove formation protrusions are intersected.

A method for manufacturing light-emitting diode devices according to the present invention for achieving the second object includes:

a first step of preparing a base mold in which a plurality of concave accommodation units has been formed;

a second step of applying fluorescent resin within the accommodation units;

a third step of simultaneously obtaining a plurality of light-emitting diode devices by disposing light-emitting diode chips, each having a smaller width than the accommodation unit, within the accommodation units in such a manner that the fluorescent resin climbs up a gap between a side of the accommodation unit and the light-emitting diode chip to be upward pushed and the side of the light-emitting diode chip is surrounded by the fluorescent resin; and

a fourth step of separating the light-emitting diode devices from the base mold.

It is preferred that the light-emitting diode chip has a flip chip type and is mounted on the accommodation unit with a substrate facing up and the light-emitting diode chip facing down in the state in which conductive bumps have been attached to the substrate.

It is preferred that the light-emitting diode chip is spaced apart from a bottom surface of the accommodation unit so that the fluorescent resin is present between the bottom surface of the accommodation unit and the light-emitting diode chip.

It is preferred that the substrate is disposed to extend to an entrance of the accommodation unit.

It is preferred that alignment means for aligning the substrate and the base mold is disposed in at least one of the base mold and the substrate so that the light-emitting diode chip is positioned at a required location within the accommodation unit.

It is preferred that the fluorescent resin in the second step is a liquid state in which a plurality of fluorescent substance particles has been dispersed, a hardening process for changing the fluorescent resin from the liquid state to a solid state is performed after the third step, and the fourth step is performed after the hardening process is performed.

It is preferred that the third step is performed after a semi-hardening process for semi-hardening the fluorescent resin of the liquid state applied in the second step is performed.

In a light-emitting diode device according to the present invention for achieving the third object, a fluorescent resin layer is formed on a light-emitting diode and a buffer layer is interposed between the light-emitting diode and the fluorescent resin layer.

It is preferred that the fluorescent resin layer has a smaller refractive index than the light-emitting diode and the buffer layer has a refractive index smaller than that of the light-emitting diode and greater than that of the fluorescent resin layer.

It is preferred that the fluorescent resin layer is obtained by applying a hardening type liquefied resin composition in which fluorescent substance particles have been dispersed on the buffer layer using a spray method and then hardening the hardening type liquefied resin composition.

It is preferred that the buffer layer is disposed to cover the substrate including the light-emitting diodes in the state in which the light-emitting diodes have been installed on the substrate.

It is preferred that the buffer layer is made of a resin-series transparent substance.

A light-emitting diode device according to an example of the present invention for achieving the fourth object includes:

a reflection body having an accommodation unit of an empty space, the sidewall of the accommodation unit being inclined outward toward the upper side; and

a light-emitting diode chip disposed within the accommodation unit,

wherein scattering means is disposed on the sidewall of the accommodation unit so that light laterally discharged by the light-emitting diode chip is scattered in various directions on the sidewall of the accommodation unit.

The scattering means may include a plurality of convex lens patterns disposed on the sidewall of the accommodation unit.

It is preferred that the lens pattern is protruded from the sidewall of the accommodation unit so that the upper part of the lens pattern is more precipitously inclined than the lower part of the lens pattern.

It is preferred that the tangent of the lower part of the lens pattern is disposed to be inclined outward compared to a virtual perpendicular line in which the sidewall of the accommodation unit stands upright without being inclined.

It is preferred that the lens pattern has a longish shape up and down.

It is preferred that the reflection body is formed by injection molding.

It is preferred that the lens pattern has a greater size relatively on the upper side of the sidewall of the accommodation unit or more lens patterns are disposed relatively on the upper side of the sidewall of the accommodation unit.

The scattering pattern may be obtained by applying scattering agent resin on the sidewall of the accommodation unit.

It is preferred that the scattering agent resin includes a plurality of reflective particles. Inorganic particles, such as SiO₂, ZrO₂, or TiO₂, in addition to metal particles, such as Ag, may be selected as the reflective particles.

The scattering pattern may include a concave-convex part obtained by physically or chemically processing a surface of the sidewall of the accommodation unit. In this case, a middle pad layer may be further formed on the sidewall of the accommodation unit, and the processing may be performed on the middle pad layer to form the concave-convex part in the middle pad layer.

A light-emitting diode device according to another example of the present invention for achieving the fourth object includes:

a reflection body providing an accommodation unit of an empty space, the sidewall of the accommodation unit having outward convex curvature while being outward inclined toward the upper side; and

a light-emitting diode chip disposed within the accommodation unit so that laterally emitted light is reflected by the sidewall of the accommodation unit and directed toward the upper side of the accommodation unit.

### Advantageous Effects

In accordance with the achievement of the first object of the present invention, a problem attributable to a deviation or fragments in the cutting process is minimized because cutting is performed at a precise location along the previously partitioned boundary grooves and an actually cut portion is the bottom portion of the boundary grooves and very thin.

Furthermore, high-efficient and uniform white light can be obtained because the fluorescent substance particles to be located around the light-emitting diode chip are regularly rearranged with high density by the pressurization of the pressing mold.

Furthermore, the thickness of the fluorescent resin to be located in the surrounding of the side of the light-emitting diode chip can be accurately controlled because the fluorescent resin is cut to a minimum thickness only at a precise location along the previously partitioned boundary grooves as described above.

In accordance with the achievement of the second object of the present invention, there is no need for a process of cutting fluorescent resin in obtaining a plurality of light-emitting diode devices because the molding of fluorescent resin for a light-emitting diode chip is performed in each accommodation unit of the base mold. Accordingly, a manufacturing process is simple, and a problem attributable to a deviation or fragments in the cutting process is not generated.

Furthermore, there is an advantage in that various recipes can be immediately handled by optionally using the base mold because the thickness of fluorescent resin to be located in the surrounding of a light-emitting diode chip can be adjusted by controlling the size of the accommodation unit.

Furthermore, the waste of fluorescent resin can be reduced because there is no fluorescent resin wasted as remnants in the process of completing a light-emitting diode device if a proper amount of the fluorescent resin is applied.

In accordance with the achievement of the third object of the present invention, light extraction efficiency can be improved and the heat deterioration of the fluorescent resin layer is prevented because the buffer layer is interposed between the light-emitting diode chip and the fluorescent resin layer and the buffer layer has a refractive index smaller than that of the light-emitting diode and greater than that of the fluorescent resin layer.

In accordance with the achievement of the fourth object of the present invention, a color deviation according to an angle is reduced because scattering is generated in various directions in the accommodation unit sidewall by the scattering means and thus light emitted by the light-emitting diode chip regularly affects the entire space of the accommodation unit compared to a conventional technology.

### DESCRIPTION OF DRAWINGS

FIG. 1 is a diagram for illustrating a conventional method for manufacturing a white light-emitting diode device;

FIG. 2 is a diagram for illustrating a method for manufacturing light-emitting diode devices according to a first embodiment of the present invention;

FIG. 3 is a diagram for illustrating an example of a pressing mold 200 according to the present invention;

FIG. 4 is a diagram for illustrating a case where through holes C are further formed in a fluorescent resin 110 in FIG. 2;

FIG. 5 is a diagram for illustrating another example of a pressing mold 100 according to the present invention;

FIG. 6 is a diagram for illustrating a method for manufacturing light-emitting diode devices according to a second embodiment of the present invention;

FIGS. 7 to 9 are diagrams for illustrating alignment means 340;

FIG. 10 is a diagram for illustrating a light-emitting diode device according to a third embodiment of the present invention;

FIG. 11 is a diagram for illustrating advantages of a spray process;

FIGS. 12 and 13 are diagrams for illustrating a conventional light-emitting diode device;

FIG. 14 is a diagram for illustrating a light-emitting diode device according to a fourth embodiment of the present invention;

FIGS. 15 to 18 are diagrams for illustrating lens patterns 650 of FIG. 14;

FIG. 19 is a diagram for illustrating a light-emitting diode device according to a fifth embodiment of the present invention;

FIG. 20 is a diagram for illustrating a light-emitting diode device according to a sixth embodiment of the present invention; and

FIG. 21 is a diagram for illustrating a light-emitting diode device according to a seventh embodiment of the present invention.

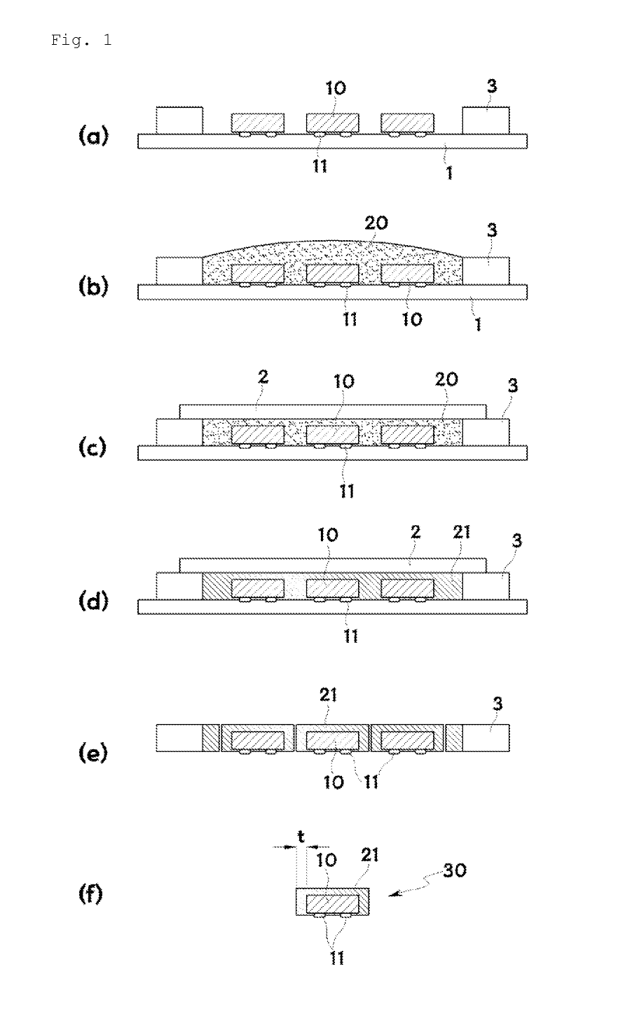

### DESCRIPTION OF REFERENCE NUMERALS

1: first sheet
3: spacer
10: light-emitting diode chip
11: conductive bump
20: resin composition
21: fluorescent resin
30: light-emitting diode device
100: fluorescent resin
110: fluorescent substance particle
200: pressing mold
210: mold body
220: chip accommodation unit formation protrusion
230: boundary groove formation protrusion
240: through hole formation protrusion
300: base mold
320: fluorescent resin
321: fluorescent substance particle
330, 410: substrate
340: alignment means
415: buffer layer
420: fluorescent resin layer
501, 601: accommodation unit
502, 602: accommodation unit sidewall
510, 610: reflection body
511, 611: lead frame
520, 620: light-emitting diode chip
521: bonding wire
522, 622: bump
530: solid fluorescent sheet
540, 640: transparent sealant
630: fluorescent layer
650: lens pattern
651: tangent
652: perpendicular line
660: scattering agent resin layer
661: spray 670: concave-convex part
A: chip accommodation unit
B: boundary groove
C: through hole

### MODE FOR INVENTION

Hereinafter, preferred embodiments of the present invention are described in detail with reference to the accompanying drawings. The following embodiments have been proposed only for the understanding of the contents of the present invention, and a person having ordinary skill in the art may change the present invention in many ways without departing from the technical spirit of the present invention. Accordingly, the range of right of the present invention should not be construed as being limited to the embodiments.

### First Embodiment

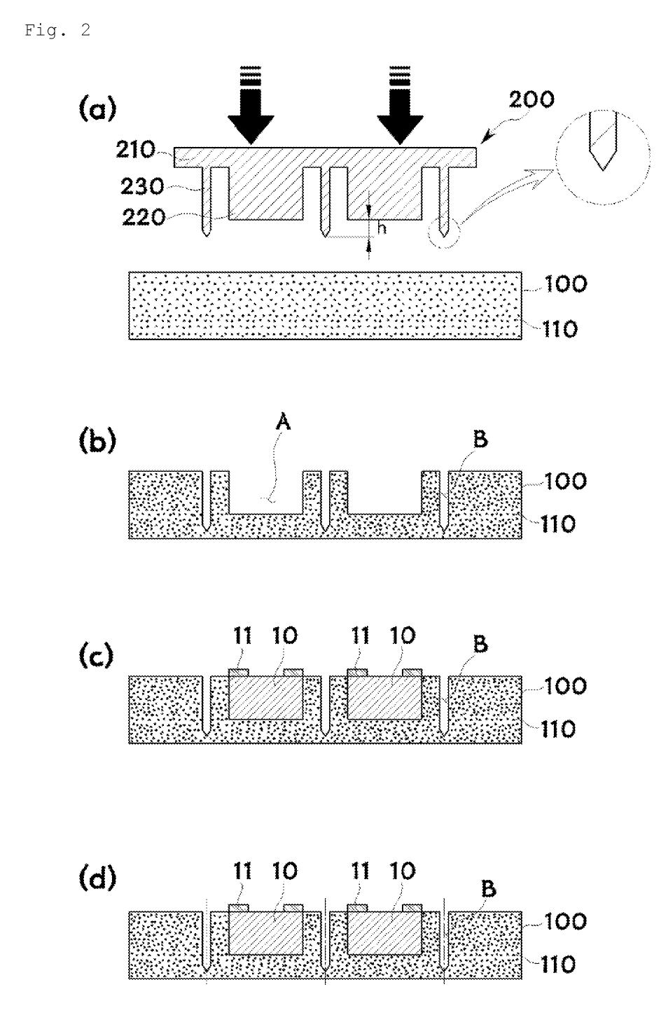

FIG. 2 is a diagram for illustrating a method for manufacturing light-emitting diode devices according to a first embodiment of the present invention, and FIG. 3 is a diagram for illustrating a pressing mold 200 which is used to form fluorescent resin 100 of FIG. 2.

As shown in FIG. 3, the pressing mold 200 includes a mold body 210, a chip accommodation unit formation protrusion 220, and a boundary groove formation protrusion 230. The boundary groove formation protrusion 230 is for forming boundary grooves B in the fluorescent resin 100, and a plurality of the boundary groove formation protrusion is protruded from the mold body 210. The chip accommodation unit formation protrusion 220 is for forming a concave chip accommodation unit A in the fluorescent resin 100, and a plurality of the chip accommodation unit formation protrusions is protruded from the mold body 210 so that the chip accommodation unit formation protrusion is located between the boundary groove formation protrusions 230. It is preferred that the boundary groove formation protrusions 230 are disposed to surround the surrounding of the chip accommodation unit formation protrusion 220.

When the pressing mold 200 is pressurized against the fluorescent resin 100 as in FIG. 2A, the plurality of concave chip accommodation units A is formed in the fluorescent resin 100 as in FIG. 2B. At the same time, the boundary grooves B are formed at locations spaced apart from the chip accommodation unit A in such a way as to surround the chip accommodation unit A. A base film may have been disposed under the fluorescent resin 100, but has not been shown in FIG. 2.

Next, after light-emitting diode chips 10 are accommodated in the chip accommodation units A as in FIG. 2C, the bottom portion of the boundary grooves B are cut as in FIG. 2D, thereby obtaining a plurality of light-emitting diode devices in each of which the light-emitting diode chip 10 has been surrounded by the fluorescent resin 100. If the light-emitting diode chip 10 is the flip chip type, it is preferred that conductive bumps 11 are accommodated in the chip accommodation unit A in such a way to be directed upward.

In the present invention, as in FIG. 2D, the substantial cutting of the fluorescent resin 100 is performed with respect to only the bottom portion of the boundary grooves B. In this case, a cutting work may be easily performed as the thickness of the bottom of the boundary groove B is small. To this end, it is preferred that the boundary groove formation protrusion 230 of the pressing mold 200 is protruded longer than the chip accommodation unit formation protrusion 220 so that the boundary groove B is formed to be deeper than the chip accommodation unit A. Reference numeral “h” indicates a difference between the depths of the boundary grooves B and the chip accommodation unit A.

The cutting of the bottom portion of the boundary groove B may be performed by breaking the bottom portion by a hand or by cutting the bottom portion using a tool. At this time, it is preferred that the bottom surface of the boundary groove B is pointed and caved in a wedge form so that the cutting is easily performed at an accurate location. To this end, it is preferred that the protruded end of the boundary groove formation protrusion 230 of the pressing mold 200 is tapered to a point in a wedge form.

A plurality of fluorescent substance particles 110 has been dispersed in the fluorescent resin 100. When the pressing mold 200 is applied as in FIG. 2A, it is preferred that the fluorescent resin 100 has a semi-solid state so that the pressing work is smoothly performed. In this case, the semi-solid state refers to a degree that the fluorescent resin 100 is slightly soft without reaching the state in which the fluorescent resin 100 is fully hardened and stiff to the extent that the pressing of the fluorescent resin 100 is difficult.

A hardening process for stiffly hardening the fluorescent resin 100 may be performed after the chip accommodation units A and the boundary grooves B are formed as in FIG. 2B or may be performed using a proper method, such as heat or ultraviolet rays, after the light-emitting diode chips 10 are accommodated as in FIG. 2C. It is preferred that cutting, such as that in FIG. 2D, is performed in the state in which the fluorescent resin 100 has been hardened by the hardening process as described above.

Meanwhile, if the pressing process is performed in the state in which the fluorescent resin 100 is soft as in FIG. 2A, the fluorescent substance particles 110 are rearranged by a force that presses the fluorescent resin 100 in the process in which the shape of the fluorescent resin 100 is changed by pressurization. Accordingly, the fluorescent substance particles 110 have higher density around the chip accommodation unit formation protrusion 220 and the boundary groove formation protrusion 230 and are distributed more uniformly. Accordingly, an effect of uniform light emission around the light-emitting diode chip 10 can be obtained.

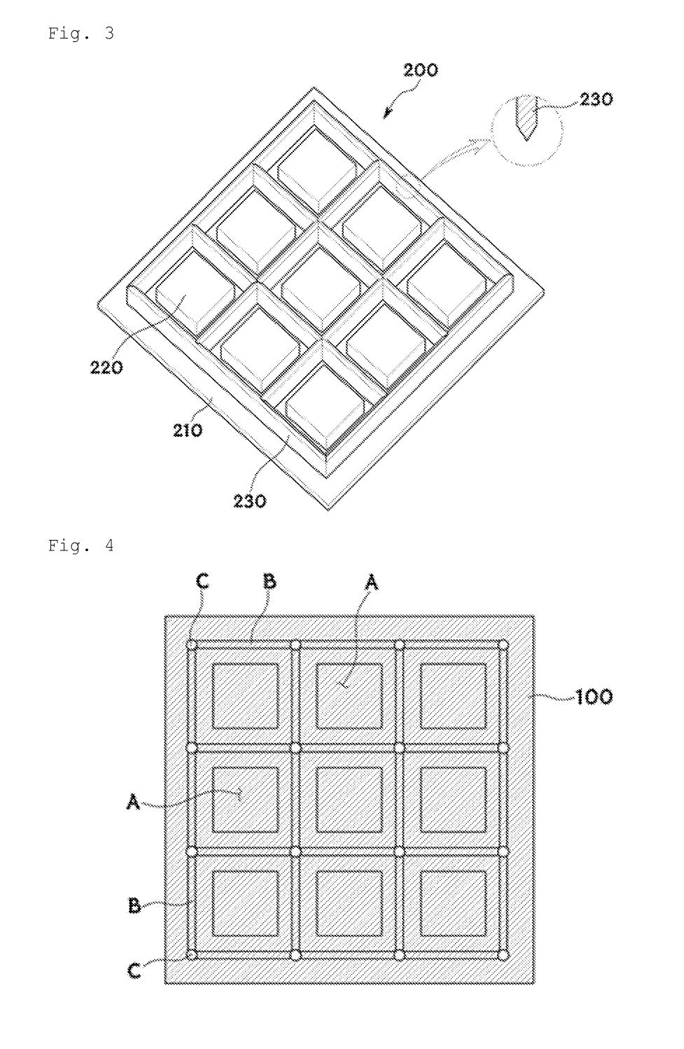

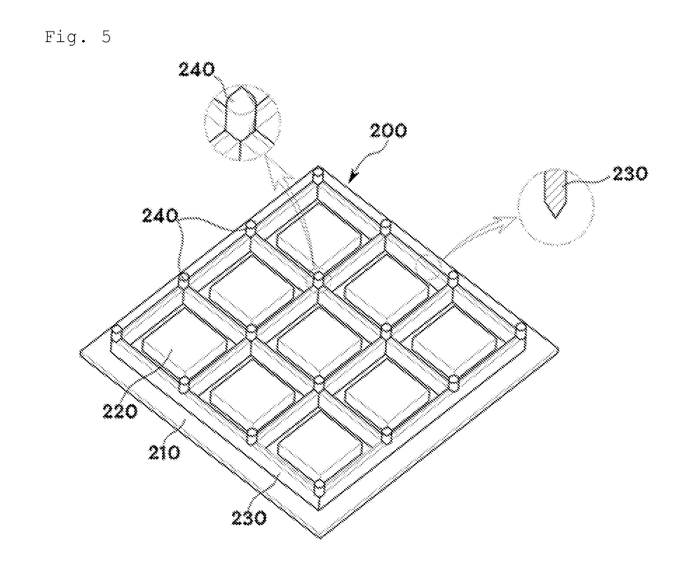

FIG. 4 is a diagram showing the fluorescent resin 100 of FIG. 2B which is viewed from the top and shows a case where through holes C penetrating the fluorescent resin 110 are further formed. Furthermore, FIG. 5 is a diagram for illustrating the pressing mold 200 suitable for being used in this case.

If the boundary grooves B surround the chip accommodation unit A, it may be inconvenient to cut the bottom portion of the boundary grooves B. It is preferred that the through hole C fully penetrating the fluorescent resin 100 is formed at a portion where the boundary grooves B are intersected so that such cutting is performed more easily. In this case, a through hole formation protrusion 240 may be further protruded and disposed at the portion where the boundary groove formation protrusion 230 are intersected in the pressing mold 100.

As described above, in accordance with the first embodiment of the present invention, a problem attributable to a deviation or fragments in the cutting process is minimized because cutting is performed at an accurate location along the previously partitioned boundary grooves B and an actually cut portion is the bottom portion of the boundary grooves B and very thin.

Furthermore, high-efficient and uniform white light can be obtained because the fluorescent substance particles to be located in the surrounding of the light-emitting diode chip 10 are regularly rearranged with high density by the pressurization of the pressing mold.

Furthermore, the thickness of the fluorescent resin 100 to be located in the surrounding of the side of the light-emitting diode chip 10 can be controlled very precisely because the fluorescent resin 100 is cut to only a minimum thickness at an accurate location along the previously partitioned boundary grooves B as described above.

### Second Embodiment

FIG. 6 is a diagram for illustrating a method for manufacturing light-emitting diode devices according to a second embodiment of the present invention. First, a base mold 300 in which a plurality of concave accommodation units A has been formed is prepared as shown in FIG. 6A, and fluorescent resin 320 is applied on the accommodation units A as shown in FIG. 6B. At this time, it is preferred that the fluorescent resin 320 has a liquid state in which a plurality of fluorescent substance particles 321 has been dispersed.

Next, as shown in FIG. 6C, in the state in which the conductive bumps 11 of light-emitting diode chips 10 have been attached to a substrate 330, the substrate 330 and the base mold 300 are aligned so that the light-emitting diode chips 10 are mounted on required locations within the accommodation units A in the state in which the substrate 330 is faced up and the light-emitting diode chip 10 is faced down. In this case, the light-emitting diode chip 10 has a smaller width than the accommodation unit A.

Thereafter, as shown in FIG. 6D, the substrate 330 is brought close to the base mold 300, thereby mounting the light-emitting diode chips 10 on the accommodation units A. At this time, the light-emitting diode chip 10 forces its way into the fluorescent resin 320 while being pressed by an external force. Accordingly, the fluorescent resin 320 is crawled up along the gap between the side of the accommodation unit A and the light-emitting diode chip 10, so the side of the light-emitting diode chip 10 is surrounded by the fluorescent resin 320.

It is preferred that the fluorescent resin 320 is also present on the side opposite the conductive bumps 11 of the light-emitting diode chip 10. To this end, the light-emitting diode chip 10 needs to be spaced apart from the bottom surface of the accommodation unit A. This may be reliably implemented in such a manner that the thickness of the light-emitting diode chip 10 is made smaller than the depth of the accommodation unit A and the substrate 330 is extended at the entrance of the accommodation unit A.

In this case, assuming that the thickness of the light-emitting diode chip 10 and the depth of the accommodation unit A are constant, it is preferred that the thickness of the fluorescent resin 320 on the opposite side of the conductive bumps 11 is constant in the light-emitting diode chips 10. If the thickness of the fluorescent resin 320 is to be made different in the light-emitting diode chips 10 through a single molding process, the size of the accommodation unit A or the light-emitting diode chip 10 has only to be adjusted. Accordingly, it is very preferred that the present invention can handle various recipes.

After the light-emitting diode chips 10 are disposed within the accommodation units A, they experience a hardening process for hardening the fluorescent resin 320. Thereafter, a plurality of light-emitting diode devices in each of which the light-emitting diode chip 10 has been surrounded by the fluorescent resin 320 is obtained at the same time by separating the substrate 130 and the base mold 300 are separated as in FIG. 6E.

The substrate 330 may play a role of a circuit board for the electrical connection of the conductive bumps 11 or may play a role of a dummy substrate for simply supporting the light-emitting diode chips 10. In the latter case, after the process of FIG. 6E, the substrate 330 will be removed from the light-emitting diode devices.

If the fluorescent resin 320 is present in a liquid state for a long time, there is a possibility that the fluorescent substance particles 321 included in the fluorescent resin 320 may be irregularly distributed because they sink due to gravity. In order to solve such a problem, a process of semi-hardening the fluorescent resin 320 may be accompanied before the fluorescent resin 320 is hardened.

In this case, semi-hardening means that the fluorescent resin 320 has been hardened from the liquid state to a soft state to the extent that the shape of the fluorescent resin 320 can be changed by the pressurization of the light-emitting diode chip 10. In the semi-hardening state, the sinking of the fluorescent substance particles 321 is rarely generated because viscosity of the fluorescent resin 320 is high compared to the case of a liquid phase.

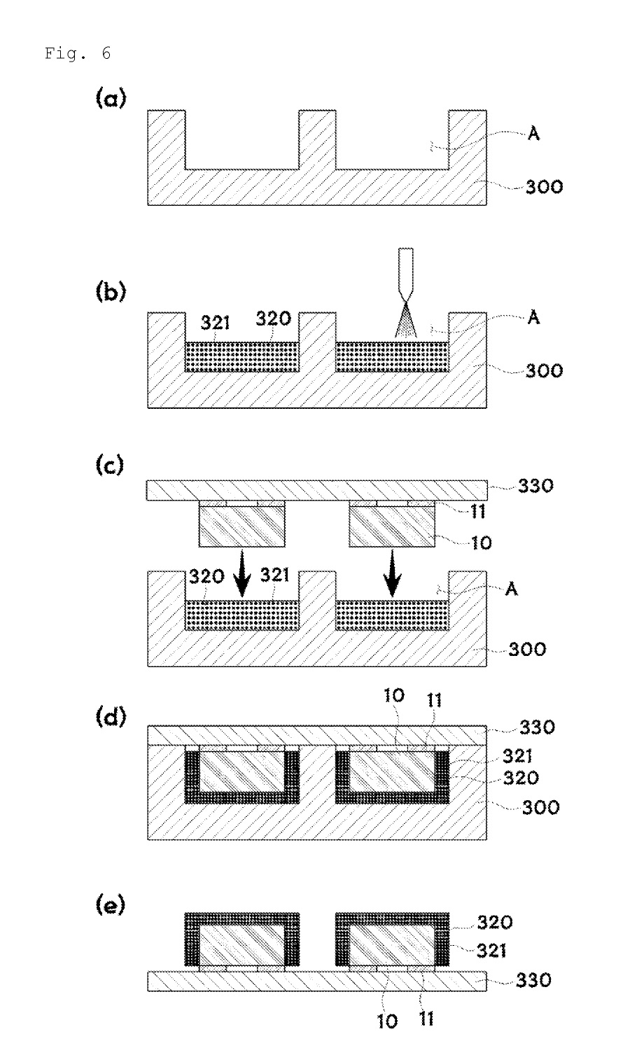

FIGS. 7 to 9 are diagrams for illustrating alignment means 340. The alignment means 340 is disposed in at least one of the base mold 300 and the substrate 330, and functions to dispose the base mold 300 and the substrate 330 at their right positions so that they are not crossed.

FIG. 7 shows a case where trapping jaws are formed in the substrate 330 as the alignment means 340 so that the base mold 300 is matched with and inserted into the trapping jaws. The trapping jaws may be disposed on the side of the base mold 300 or may be disposed on both sides of the substrate 330 and the base mold 300.

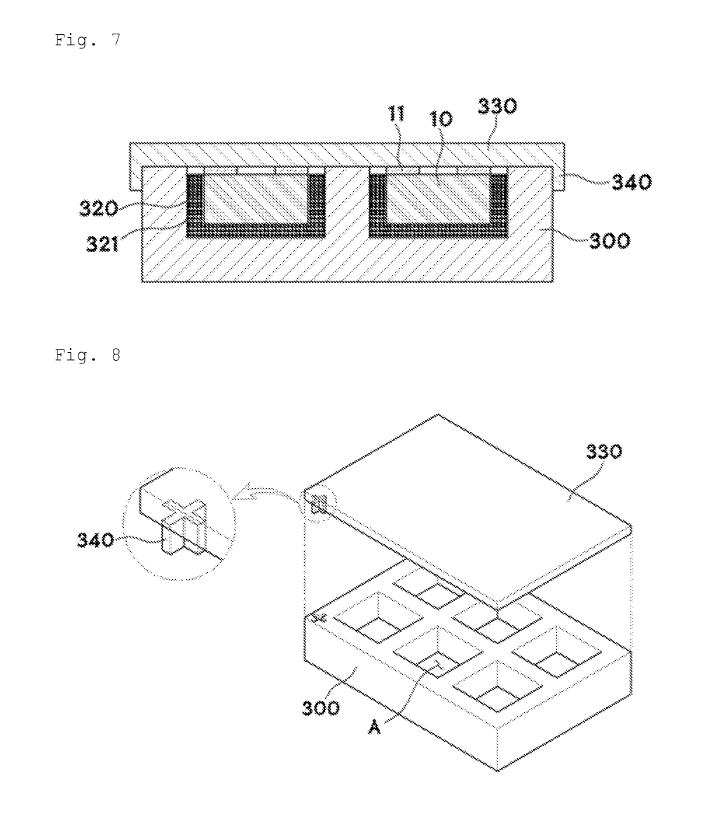

FIGS. 8 and 9 show cases where marks coincident with the base mold 300 and the substrate 330 are formed as the alignment means 340, and show cases where the marks are formed in the base mold 300 and the substrate 330 as embossing and engraving, respectively, so that the marks are mutually matched and inserted.

If the mark can assign directivity as a cross, for example, as in FIG. 8, alignment may be performed by only a single mark. If the mark cannot assign directivity even as a circle as in FIG. 9, the mark is preferred for alignment only if at least two or more marks are disposed.

As described above, in accordance with the second embodiment of the present invention, a process of cutting the fluorescent resin 320 is not required in obtaining a plurality of light-emitting diode devices because the molding of the fluorescent resin 320 for the light-emitting diode chip 10 in each of the accommodation units A of the base mold 300 is performed. Accordingly, a manufacturing process can be simplified, and a problem attributable to a deviation or fragments in the cutting process is not generated.

Furthermore, there is an advantage in that various recipes can be immediately handled by optionally using the base mold 300 because the thickness of the fluorescent resin 320 that may be present in the surrounding of the light-emitting diode chip 10 can be adjusted by controlling the size of the accommodation unit A.

Furthermore, the waste of the fluorescent resin 320 can be reduced because the fluorescent resin 320 discarded as remnants in the process of completing the light-emitting diode device is not practically present if a proper amount of the fluorescent resin 320 is applied.

### Third Embodiment

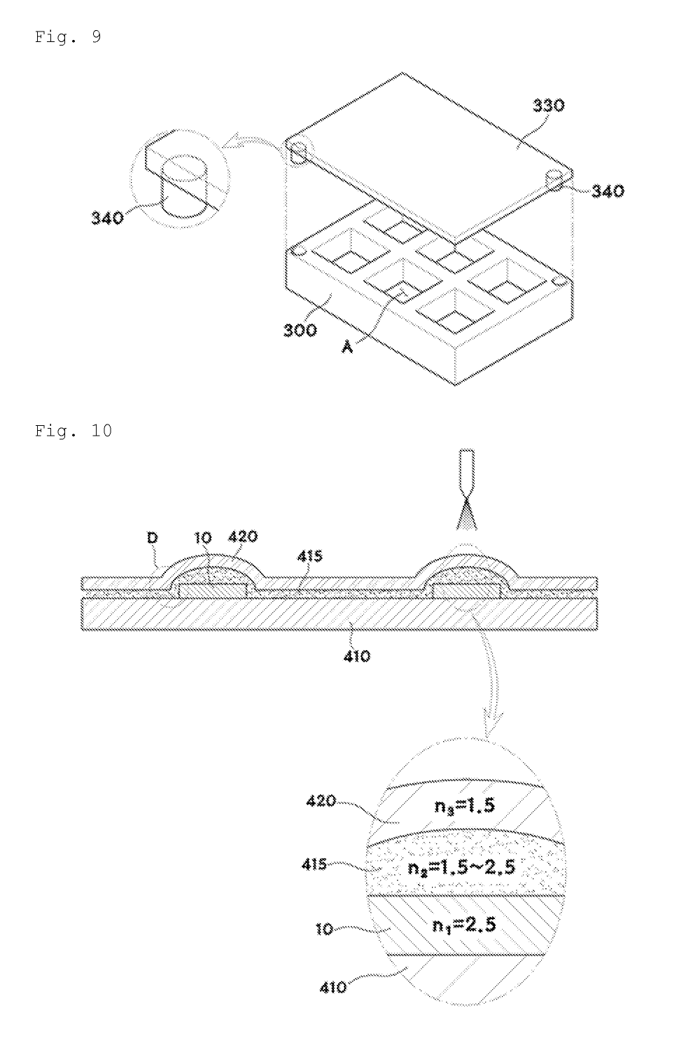

FIG. 10 is a diagram for illustrating a light-emitting diode device according to a third embodiment of the present invention. As shown in FIG. 10, in the light-emitting diode device according to the third embodiment of the present invention, a fluorescent resin layer 420 is formed over a light-emitting diode chip 10, but a buffer layer 415 is further disposed between the light-emitting diode chip 10 and the fluorescent resin layer 420.

The buffer layer 415 is for preventing the fluorescent resin layer 420 from being deteriorated due to heat generated by the light-emitting diode chip 10. If the thermal conductivity of the buffer layer 415 is too small, the light-emitting diode chip 10 may be deteriorated because heat discharged by the light-emitting diode chip 10 is not discharged to the outside. Accordingly, the buffer layer 415 needs to have thermal conductivity of some degree.

The heat may climb the buffer layer 415 and may be laterally lost due to the presence of the buffer layer 415, or heat energy will be consumed by the buffer layer 415 itself. As a result, thermal damage to the fluorescent resin layer 420 is minimized because the amount of heat that reaches the fluorescent resin layer 420 is reduced.

It is preferred that the fluorescent resin layer 420 is formed by coating a hardening type liquefied resin composition in which a plurality of fluorescent substance particles has been dispersed through a spray. The reason for this is that light extraction efficiency is further improved because a degree of dispersion of fluorescent substance particles 421 is increased by the spray process compared to other processes, as shown in FIG. 11. FIG. 11A shows a case where using other processes, and FIG. 11B shows a case using the spray process.

However, it is practically very difficult to perform the spray process on each of the light-emitting diode chips 10. Accordingly, it is preferred that such a spray process is performed in the state in which a plurality of the light-emitting diode chips 10 has been mounted on a substrate 410.

In this case, if the buffer layer 415 is not present, light emitted to the side of the light-emitting diode chip 10 does not experience the fluorescent resin layer 420 because the spray coating is rarely performed on a step portion with the substrate 410, that is, on the side of the light-emitting diode chip 10, thereby generating a color deviation for each color.

However, if the buffer layer 415 is first formed to cover the substrate 410 including the light-emitting diodes 10 and the fluorescent resin layer 420 is then coated on the buffer layer 415 by spray as in the present invention, the fluorescent resin layer 420 preferably has a generally uniform thickness and also has a gentle curve so that it can digest light emitted to the side of the light-emitting diode chip 10 as indicated by reference numeral D.

The substrate 410 may play a role of a circuit board for electrical connection with the light-emitting diode chips 10 or may play a role of a dummy substrate for simply supporting the light-emitting diode chips 10 in a manufacturing process.

If the light-emitting diode chip 10 and the fluorescent resin layer 420 are spaced apart so that an empty space not including the buffer layer 415 is formed between the light-emitting diode chip 10 and the fluorescent resin layer 420, it results in the sequence of the “light-emitting diode chip 10-empty space (air)-fluorescent resin layer 420-external space (air)”. In this case, the refractive index of air is 1 and thus the empty space has a smaller refractive index than the fluorescent resin layer 420, and thus it is not preferred because light generated by the light-emitting diode chip 10 is difficult to be drawn to the external space.

Accordingly, as in the present invention, the buffer layer 415 having a refractive index smaller than that of the light-emitting diode chip 10 and greater than that of the fluorescent resin layer 420 is interposed between the light-emitting diode chip 10 and the fluorescent resin layer 420 in order to form the sequence of the “light-emitting diode chip 10-buffer layer 415-fluorescent resin layer 420-external space (air)”, thereby preferably improving light extraction efficiency.

Such a structure of the present invention has an advantage in that light extraction efficiency is better because the refractive index slowly changes from a high value to a low value between the light-emitting diode chip 10 and the external space (air), compared to a conventional structure, such as the “light-emitting diode chip 10-fluorescent resin layer 420.” FIG. 10 shows an example in which the light-emitting diode chip 10 has a refractive index n1 of 2.5, the buffer layer 415 has a refractive index n2 of 1.5˜2.5, and the fluorescent resin layer 420 has a refractive index n3 of 1.5.

It is preferred that the buffer layer 415 is made of transparent resin series so that light generated by the light-emitting diode chip 10 can reach the fluorescent resin layer 420.

As described above, in accordance with the third embodiment of the present invention, the buffer layer 415 is interposed between the light-emitting diode chip 10 and the fluorescent resin layer 420, and the buffer layer 415 has a refractive index smaller than that of the light-emitting diode chip 10 and greater than that of the fluorescent resin layer 420. Accordingly, light extraction efficiency is improved and the heat deterioration of the fluorescent resin layer 420 is prevented.

### Fourth Embodiment

FIG. 14 is a diagram for illustrating a light-emitting diode device according to a fourth embodiment of the present invention. As shown in FIG. 14, a reflection body 610 includes an accommodation unit 601 of an empty space for accommodating a light-emitting diode 620. The sidewall 602 of the accommodation unit 601 is disposed to be outward inclined toward the upper side, and thus has a shape upward widened like a funnel when it is generally viewed.

A lead frame 611 is disposed to be exposed to the accommodation unit 601. The light-emitting diode 620 is disposed to be electrically connected to the lead frame 611 through bumps 622. The accommodation unit 601 is filled with a transparent sealant 640, for example, silicon resin. The transparent sealant 640 functions to disperse light and also to prevent moisture or oxygen from penetrating into the light-emitting diode 620. FIG. 14A shows the state in which the transparent sealant 640 has been omitted for convenience of understanding of the accommodation unit 601.

FIG. 14 shows a case where a fluorescent layer 630 has been stacked on only the light-emitting diode 620, but is not limited thereto. The fluorescent layer 630 may be disposed to block the entire entrance of the accommodation unit 601 as in a conventional technology.

The electrical connection of the light-emitting diode 620 and the lead frame 611 may be performed through bonding wires in addition to the bumps 622 as described above in the previous conventional technology. If the fluorescent layer 630 is disposed in such a way as to be directly stacked on the light-emitting diode chip 620 as in FIG. 14, it is difficult to properly provide a portion that will connect bonding wires in the light-emitting diode chip 620. Accordingly, it is preferred that the flip chip type is adopted as described above.

Scattering means S is disposed in the accommodation unit sidewall 602 so that light laterally emitted by the light-emitting diode chip 620 is scattered in various directions in the accommodation unit sidewall 602. The scattering means S may be implemented in various forms. FIG. 14 shows an example in which a plurality of convex lens patterns 650 has been disposed in the accommodation unit sidewall 602.

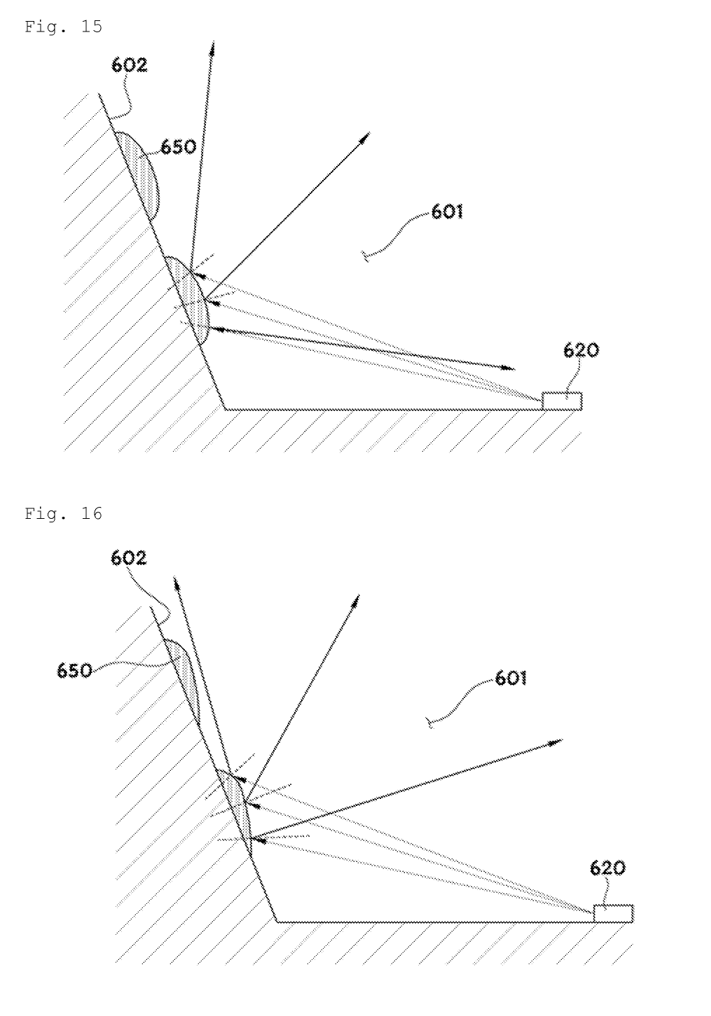

FIGS. 15 to 18 are diagrams for illustrating the lens patterns 650 of FIG. 14.

As shown in FIG. 15, if the lens pattern 650 is present, light laterally emitted by the light-emitting diode chip 620 is scattered in various directions by the lens pattern 650. When blue light by the light-emitting diode chip 620 and yellow light by the fluorescent layer 630 are mixed in the upper space of the light-emitting diode chip 620, a color deviation is reduced because such mixing is regularly performed on the entire space of the accommodation unit 601 compared to a conventional technology.

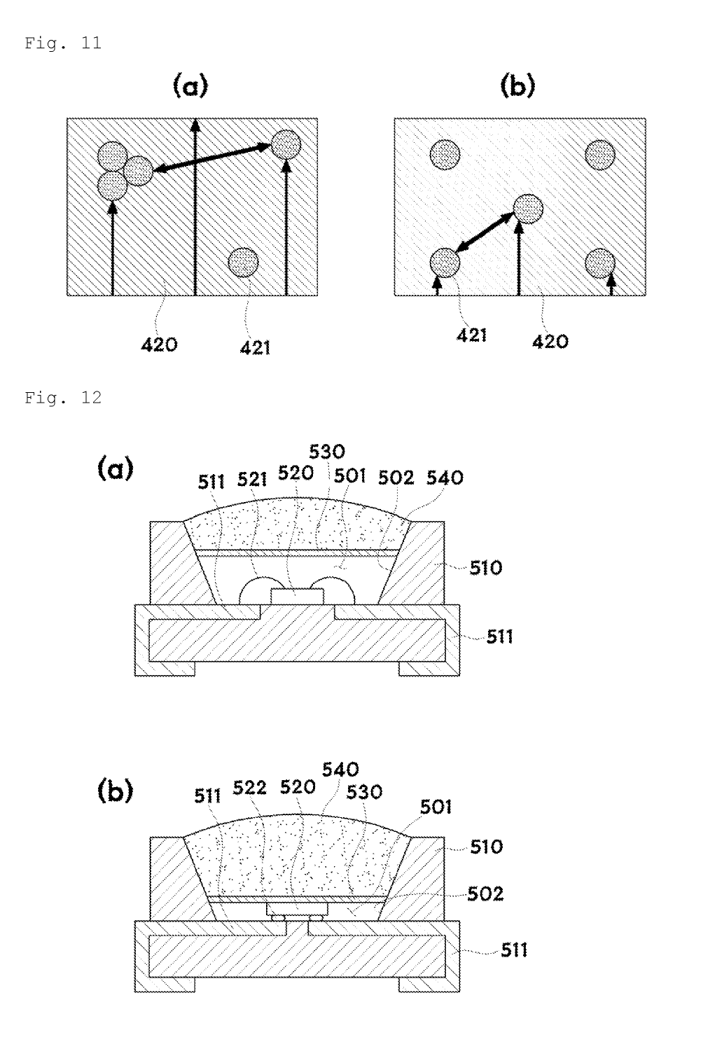

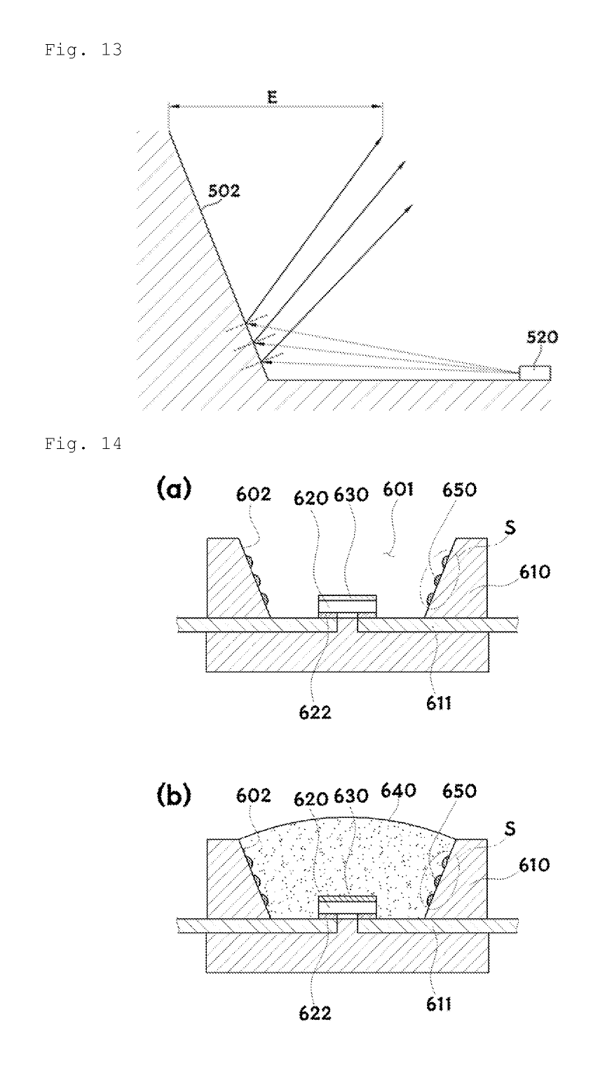

If the fluorescent layer 630 is widely disposed to block the entire entrance of the accommodation unit 601 as in reference numeral 530 of FIG. 12, light is scattered in various directions by the accommodation unit sidewall 602. Accordingly, the same color deviation reduction effect can be obtained because light emitted by the light-emitting diode 620 influences the entire fluorescent layer 630.

As shown in FIG. 16, if the slope of the upper part of the lens pattern 650 is more precipitously protruded than the slope of the lower part of the lens pattern 650, a reduction of a color deviation can be doubled because light that collides against the upper part of the lens pattern 650 can be further scattered toward the edge of the accommodation unit 601.

Meanwhile, the reflection body 610 according to the present invention may be made of a resin substance, such as polycarbonate, and fabricated by injection molding. If the reflection body 610 is fabricated by injection molding as described above, the mold has to be able to be removed after molding.

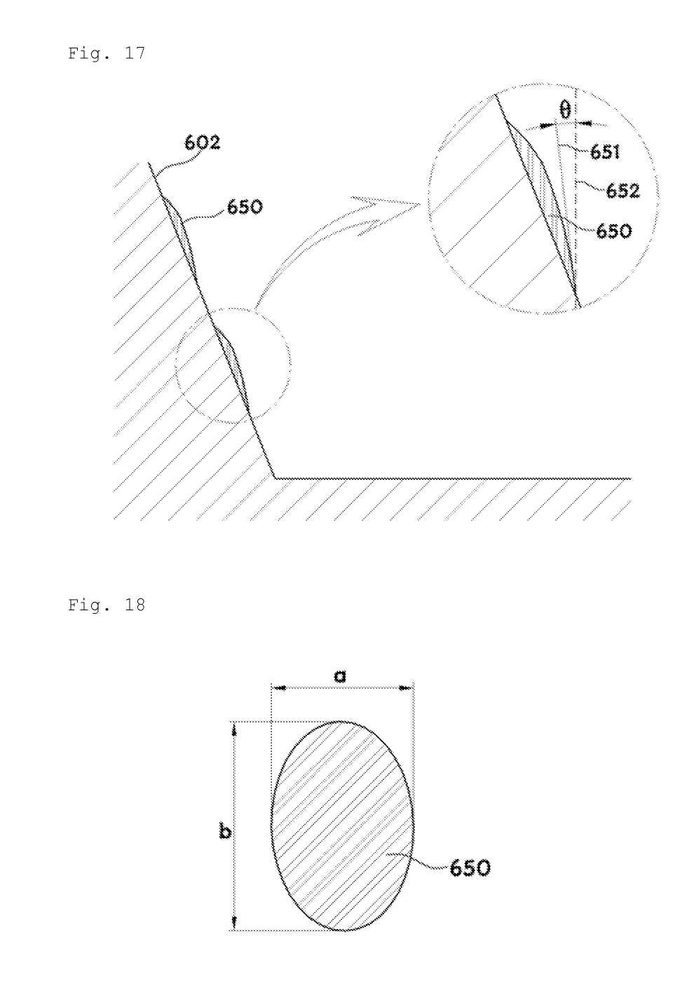

To this end, as shown in FIG. 17, it is preferred that the lens pattern 650 is disposed so that the tangent 651 of the lower part of the lens pattern 650 is more outward inclined than a perpendicular line 652. In this case, the perpendicular line 652 refers to a virtual line in which the accommodation unit sidewall 2 stands upright without being inclined.

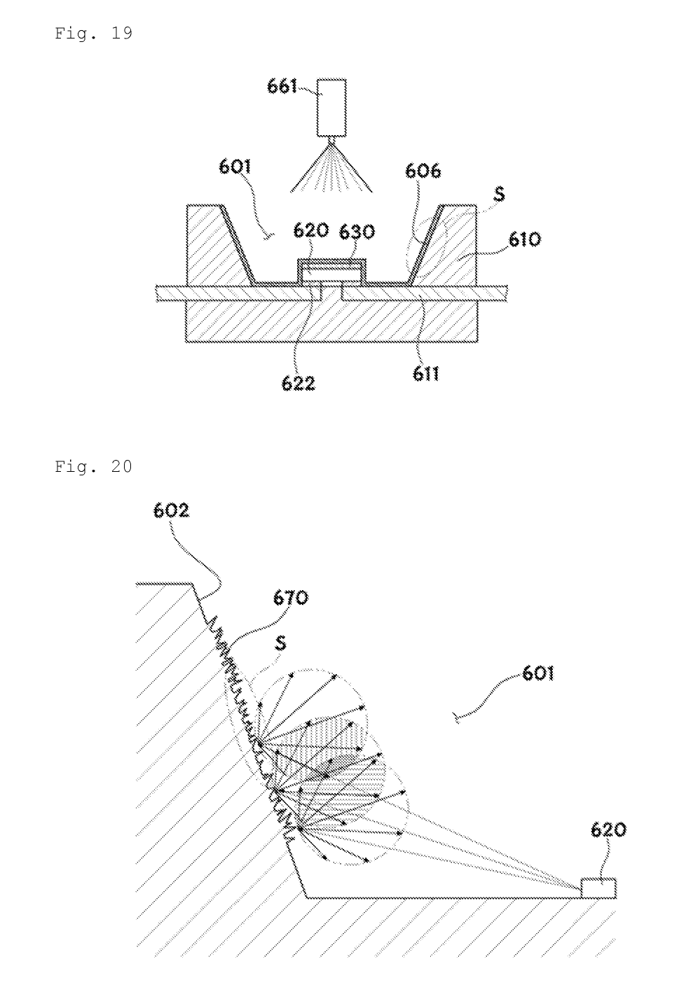

An engraving pattern may be formed on the side of a mold used for injection molding so that it corresponds to the lens pattern 650. The reason for this is that the lens pattern 650 must be able to be easily pulled out from the engraving pattern when the mold is upraised from the reflection body 610 and detached after molding. In this case, it is more preferred that the lens pattern 650 has a longish shape up and down (a<b) as in FIG. 18 so that the mold is pulled out from the lens pattern 650.

The area of the accommodation unit sidewall 602 is widened toward the upper side because the accommodation unit 601 has a form that upward widens like a funnel. If the lens patterns 650 have the same size, more lens patterns 650 may need to be present in the upper part of the accommodation unit sidewall 602 than in the lower part of the accommodation unit sidewall 602. If the same number of lens patterns 650 is formed in the lower and upper parts of the accommodation unit sidewall 602, the lens pattern 650 at the upper part needs to be greater. It is preferred that a ratio of the lens patterns 650 in the lower part of the accommodation unit sidewall 602 and a ratio of the lens patterns 650 in the upper part of the accommodation unit sidewall 602 are the same so that uniform scattering is performed.

### Embodiment 5

FIG. 19 is a diagram for illustrating a light-emitting diode device according to a fifth embodiment of the present invention. In FIG. 19, the scattering means S is obtained by applying scattering agent resin through a spray 661.

FIG. 19 shows a case where a scattering agent resin layer 660 is formed on the bottom of the accommodation unit and on the light-emitting diode 620 in addition to the accommodation unit side 602 by applying the scattering agent resin to the accommodation unit 601 in the state in which the light-emitting diode 620 has been mounted on the reflection body 610, but is not limited thereto. The scattering agent resin may be applied to only the accommodation unit side 602 using a mask before or after the light-emitting diode 620 is mounted.

The scattering agent resin is a scattering agent, and it is preferred that the scattering agent resin includes a plurality of reflective particles. In this case, scattering may be performed in various directions by the dispersion of the reflective particles. Inorganic particles, such as SiO₂, ZrO₂, or TiO₂, in addition to metal particles, such as Ag, may be selected as the reflective particles.

### Embodiment 6

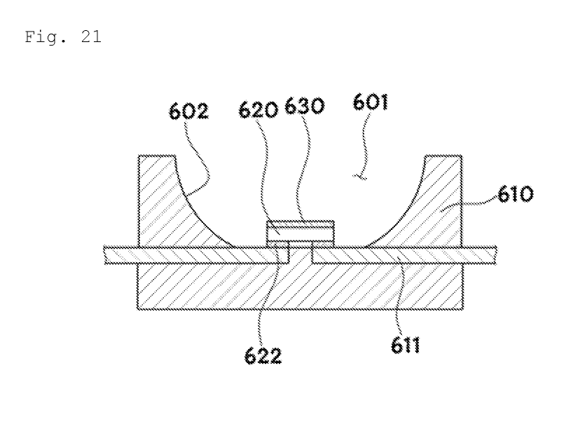

FIG. 20 is a diagram for illustrating a light-emitting diode device according to a sixth embodiment of the present invention. In FIG. 20, the scattering means S includes a concave-convex part 670 obtained by physically or chemically processing a surface of the accommodation unit sidewall 602. In this case, it is preferred that the light-emitting diode 620 is disposed after the concave-convex part 670 is formed so that the light-emitting diode 620 is not physically or chemically damaged.

Scattering in various directions is performed because roughness is assigned to the accommodation unit sidewall 602 through physical or chemical processing. An example of such chemical processing may include a case where the accommodation unit sidewall 602 is chemically etched using an etchant. An example of such physical processing may include a case where fine particles impinge on the accommodation unit sidewall 602.

If direct processing for the accommodation unit sidewall 602 is difficult, the concave-convex part 670 may be formed by first forming a middle pad layer capable of being easily processed on the accommodation unit sidewall 602 using a spray method and then physically or chemically processing a surface of the middle pad layer.

### Embodiment 7

FIG. 21 is a diagram for illustrating a light-emitting diode device according to a seventh embodiment of the present invention and shows a case where a color deviation is reduced by assigning curvature to the accommodation unit side 602. As shown in FIG. 21, the accommodation unit sidewall 602 has outward convex curvature while being outward inclined toward the upper side. In this case, a color deviation can be reduced because light can further reach up to the edge of the accommodation unit 601 compared to a conventional case not having such curvature.

As described above, in accordance with the fourth embodiment to the seventh embodiment of the present invention, scattering is generated in various directions in the accommodation unit sidewall 602 by the scattering means S, etc. Accordingly, a color deviation according to an angle is reduced because light emitted by the light-emitting diode chip 610 regularly affects the entire space of the accommodation unit 601 compared to a conventional technology.

1. A method for manufacturing light-emitting diode devices, comprising:
a first step of preparing a base mold in which a plurality of concave accommodation units has been formed;
a second step of applying fluorescent resin within the accommodation units;
a third step of simultaneously obtaining a plurality of light-emitting diode devices by disposing light-emitting diode chips, each having a smaller width than the accommodation unit, within the accommodation units in such a manner that the fluorescent resin climbs up a gap between a side of the accommodation unit and the light-emitting diode chip to be upward pushed and the side of the light-emitting diode chip is surrounded by the fluorescent resin; and
a fourth step of separating the light-emitting diode devices from the base mold.

2. The method of claim 1, wherein the light-emitting diode chip has a flip chip type and is mounted on the accommodation unit with a substrate facing up and the light-emitting diode chip facing down in a state in which conductive bumps have been attached to the substrate.

3. The method of claim 1, wherein the light-emitting diode chip is spaced apart from a bottom surface of the accommodation unit so that the fluorescent resin is present between the bottom surface of the accommodation unit and the light-emitting diode chip.

4. The method of claim 2, wherein the substrate is disposed to extend to an entrance of the accommodation unit.

5. The method of claim 2, wherein alignment means for aligning the substrate and the base mold is disposed in at least one of the base mold and the substrate so that the light-emitting diode chip is positioned at a required location within the accommodation unit.

6. The method of claim 1, wherein:
the fluorescent resin in the second step is a liquid state in which a plurality of fluorescent substance particles has been dispersed,
a hardening process for changing the fluorescent resin from the liquid state to a solid state is performed after the third step, and
the fourth step is performed after the hardening process is performed.

7. The method of claim 6, wherein the third step is performed after a semi-hardening process for semi-hardening the fluorescent resin of the liquid state applied in the second step is performed.
